(19) United States
(12) Patent Application Publication
(10) Pub. No.: US 2025/0171039 A1
(43) Pub. Date: May 29, 2025

(54) COMPREHENSIVE SOTIF TESTING SYSTEM AND METHOD THEREOF

(71) Applicant: Automotive Research & Testing Center, Changhua County (TW)

(72) Inventors: Chih-Wei CHUANG, Changhua County (TW); Chien-An CHEN, Changhua County (TW)

(21) Appl. No.: 18/522,262

(22) Filed: Nov. 29, 2023

(51) Int. Cl. B60W 50/06

(52) U.S. Cl. CPC B60W 50/06

(57) ABSTRACT

A comprehensive SOTIF testing system includes a scene database, a virtual testing module and an analyzing module. The scene database includes a plurality of scene groups, and the scene groups respectively correspond to a plurality of source types. Each of the scene groups includes a plurality of scenes, and each of the scenes corresponds to at least one of a plurality of trigger conditions and a plurality of function limitations. The virtual testing module is configured to decide a plurality of to-be-tested members from the source types based on demands of a to-be-tested system, to choose a plurality of chosen members from the scene groups, to generate a plurality of virtual testing scenes based on the scenes of the chosen members, to test the to-be-tested system on the virtual testing scenes, and to confirm whether at least one fail member is present in the virtual testing scenes.

### BACKGROUND

### Technical Field

The present disclosure relates to a testing system and a testing method. More particularly, the present disclosure relates to a comprehensive SOTIF testing system and a comprehensive SOTIF testing method.

### Description of Related Art

Earlier simulation tests focus on the functions of the self-driving; however, the safety problems of the self-driving are not always caused by the function failure, and may be affected by the driving environment or the operation, such as the blocking of the traffic signs, the restricted sightline caused by the heavy rain and the miss operation of the driver. Hence, lots of unexpected fictional safety problems are generated. Accordingly, relevant departments design a rule, i.e., ISO 21448, relative to the safety of the intended functionality (SOTIF) to compensate the parts not being covered by the conventional functionality standard, i.e., ISO 26262, and therefore the risk of the autonomous vehicle in a known or unknown scene caused by the design deficiency or the function limitation may be controlled in an appropriate range.

Tests about SOTIF will be conducted as designing the autonomous vehicle having a level higher than LEVEL 1. However, the tests are conducted on real roads, no unified testing method and specific risk evaluating standard are used, and the consistence of the testing scenes is low. Additionally, the real road tests easily cause the safety problems of the testers. Furthermore, the real road tests are similar with the vehicle tests in testing the component function, few key scenes are tested, and the improvements are required.

Based on the aforementioned problems, how to effectively and comprehensively conducting the SOTIF test becomes a target that those in the industry pursue.

### SUMMARY

According to one embodiment of the present disclosure, a comprehensive SOTIF testing system includes a scene database, a virtual testing module and an analyzing module. The scene database includes a plurality of scene groups, and the scene groups respectively correspond to a plurality of source types. Each of the scene groups includes a plurality of scenes, and each of the scenes corresponds to at least one of a plurality of trigger conditions and a plurality of function limitations. The virtual testing module is configured to decide a plurality of to-be-tested members from the source types based on demands of a to-be-tested system, to choose a plurality of chosen members from the scene groups corresponding to the to-be-tested members, to generate a plurality of virtual testing scenes based on the scenes of the chosen members, to test the to-be-tested system on the virtual testing scenes, and to confirm whether at least one fail member is present in the virtual testing scenes. The analyzing module is configured to confirm one of the trigger conditions or one of the function limitations that the at least one fail member in the virtual testing scenes corresponds to so as to provide an improving method.

According to another aspect of the present disclosure, a comprehensive SOTIF testing method includes a scene providing step, a virtual testing step and an analyzing step. In the scene providing step, a scene database includes a plurality of scene groups, the scene groups respectively correspond to a plurality of source types, each of the scene groups includes a plurality of scenes, and each of the scenes corresponds to at least one of a plurality of trigger conditions and a plurality of function limitations. In the virtual testing step, a virtual testing module decides a plurality of to-be-tested members from the source types based on demands of a to-be-tested system, chooses a plurality of chosen members from the scene groups corresponding to the to-be-tested members, generates a plurality of virtual testing scenes based on the scenes of the chosen members, tests the to-be-tested system on the virtual testing scenes, and confirms whether at least one fail member is present in the virtual testing scenes. In the analyzing step, an analyzing module confirms one of the trigger conditions or one of the function limitations that the at least one fail member in the virtual testing scenes corresponds to so as to provide an improving method.

### BRIEF DESCRIPTION OF THE DRAWINGS

The disclosure can be more fully understood by reading the following detailed description of the embodiments, with reference made to the accompanying drawings as follows:

FIG. 1 shows a system block diagram of a comprehensive SOTIF testing system according to one embodiment of the present disclosure.

FIG. 2 shows a flow block diagram of a comprehensive SOTIF testing method according to another embodiment of the present disclosure.

FIG. 3 shows a flow chart of the comprehensive SOTIF testing method of FIG. 2.

### DETAILED DESCRIPTION

The embodiments of the present disclosure will be illustrated with drawings hereinafter. In order to clearly describe the content, many practical details will be mentioned with the description hereinafter. However, it will be understood by the reader that the practical details will not limit the present disclosure. In other words, in some embodiment of the present disclosure, the practical details are not necessary. Additionally, in order to simplify the drawings, some conventional structures and elements will be illustrated in the drawings in a simple way; the repeated elements may be labeled by the same or similar reference numerals.

In addition, the terms first, second, third, etc. are used herein to describe various elements or components, these elements or components should not be limited by these terms. Consequently, a first element or component discussed below could be termed a second element or component. Moreover, the combinations of the elements, the components, the mechanisms and the modules are not well-known, ordinary or conventional combinations, and whether the combinations can be easily completed by the one skilled in the art cannot be judged based on whether the elements, the components, the mechanisms or the module themselves are well-known, ordinary or conventional.

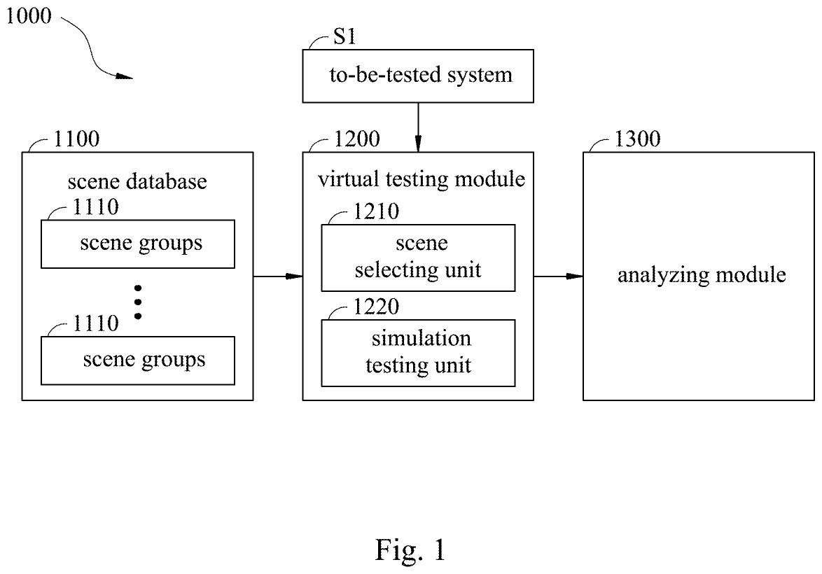

FIG. 1 shows a system block diagram of a comprehensive SOTIF testing system 1000 according to one embodiment of the present disclosure. The comprehensive SOTIF testing system 1000 includes a scene database 1100, a virtual testing module 1200 and an analyzing module 1300.

The scene database 1100 includes a plurality of scene groups 1110, and the scene groups 1110 respectively correspond to a plurality of source types. Each of the scene groups 1110 includes a plurality of scenes, and each of the scenes corresponds to at least one of a plurality of trigger conditions and a plurality of function limitations.

The virtual testing module 1200 is configured to decide a plurality of to-be-tested members from the source types based on demands of a to-be-tested system S1, to choose a plurality of chosen members from the scene groups 1110 corresponding to the to-be-tested members, to generate a plurality of virtual testing scenes based on the scenes of the chosen members, to test the to-be-tested system S1 on the virtual testing scenes, and to confirm whether at least one fail member is present in the virtual testing scenes.

The analyzing module 1300 is configured to confirm one of the trigger conditions or one of the function limitations that the at least one fail member in the virtual testing scenes corresponds to so as to provide an improving method.

Therefore, since the scene groups 1110 in the scene database 1100 respectively correspond to the source types, the scene groups 1110 that need to be tested may be chosen based on the demands of the to-be-tested system S1. Moreover, since each of the scenes corresponds to the trigger condition or the function limitation, the solving methods can be quickly found if there is any fail scene. Hence, the to-be-test system S1 may be systematically, comprehensively, and quickly tested. The details of the comprehensive SOTIF testing system 1000 may be described hereinafter.

The scene database 1100 may be stored in an electronic device, such as a computer and a server. The scenes in the scene database 1100 may be collected in advance or be designed according to the demands. Each of the scenes may correspond to one source type, and may at least correspond to one function limitation or one trigger condition. The source types may include a camera, a radar, an actuator and a human interface. The source type may further include other sensors, an interchange, a general road, or other types, the actuator may further be divided into a braking or a turning, and the disclosure is not limited thereto. The function limitation may be that the capability of the sensor is affected or that the spec of the sensor is limited. The trigger condition may be the abnormal road or the bad weather. Table 1 shows the scenes correspond to one source type, i.e., the camera. In the unsafe control action (UCA), UCA-1 represents “a control action required for safety is not provided”, and UCA-2 represents “a control action not required for safety requires to be provided”. The function limitation PL-1 may be that the camera is affected by the light, the function limitation PL-2 may be that the camera is affected by the visibility, and the function limitation PL-3 may be a blind area caused by the small FOV of the camera. The trigger condition TC-1 may be strong light emitting, and the trigger condition TC-2 may be a terminator (the tunnel entrance). The scene LS-1 may be a scene having a testing condition that the camera is affected by strong light emitting (corresponding to one function limitation and one trigger condition), the scene LS-2 may be a scene having a testing condition of a tunnel entrance terminator (corresponding to one function limitation and one trigger condition), and the scene LS-10 may be a scene having a testing condition of the camera having small FOV (corresponding to one function limitation). It is noted that, Table 1 is only an example, and the present disclosure is not limited to the content and the quantity thereof.

TABLE 1

| unsafe control action | function limitation | trigger condition | scene |
|---|---|---|---|
| UCA-1, UCA-2 | PL-1 | TC-1 | LS-1 |
| | | TC-2 | LS-2 |
| | | TC-3 | LS-3 |
| | | TC-4 | LS-4 |
| UCA-1, UCA-2 | PL-2 | TC-5 | LS-5 |
| | | TC-6 | LS-6 |
| | | TC-7 | LS-7 |
| | | TC-8 | LS-8 |
| | | TC-9 | LS-9 |
| UCA-1, UCA-2 | PL-3 | N/A | LS-10 |

The scenes of the scene database 1100 are classified based on the source types, the function limitations and/or the trigger conditions. The hazard analysis and risk assessment (HARA) may be used to identify the dangerous issues of the self-driving vehicle, then the system-theoretic process analysis (STPA) is used to obtain the trigger conditions, and the scenes may be classified, but the present disclosure is not limited thereto.

The virtual testing module 1200 indicates software or programs executed by a processor. The virtual testing module 1200 may include a scene selecting unit 1210 and a simulation testing unit 1220. The scene selecting unit 1210 can select the scenes from the scene database 1100, and the simulation testing unit 1220 can construct the virtual testing scenes for simulating tests. The simulation testing unit 1220 may be software including Matlab/Simulink, carsim and Prescan to construct virtual testing scenes (modifying the weather condition and light source), to add sensors (ideal sensors, millimeter-wave radars, and cameras) and to add controllers to conduct a closed loop controlling simulation via the dynamic model of the vehicle, but the present disclosure is not limited thereto.

As testing the to-be-test system S1, the source types have to be tested may be obtained based on the demands of the to-be-test system S1, and the source types have to be tested are defined as the to-be-tested members. Subsequently, the scene groups 1110 correspond to the to-be-tested members may be chosen by the scene selecting unit 1210 to be defined as the chosen members, and the scenes of the chosen members may be used to construct the virtual testing scenes by the simulation testing unit 1220 for testing the to-be-test system S1. For example, the demands of the to-be-test system S1 is lane keeping aid (LKA), and the source types of LKA obtained by the STPA may be the camera, the controller, the actuator and the human interface. The camera, the controller, the actuator and the human interface are the to-be-tested members. In addition, the system spec, the operation spec (including the suitable speed and the system disable conditions), and the sensor specs (including the FOV of the camera) can be inputted to conduct the simulation test.

In one embodiment, some of the scenes may be chosen, and the scenes are respectively used by the simulation testing unit to generate the virtual testing scenes corresponding thereto one by one. The tests may be ordered by the affection of the trigger conditions. For example, the scene LS-8 is a sandstorm, the scene LS-7 is a fog day, the affection of the fog day is larger, and a virtual testing scene corresponding to the scene LS-7 may be first constructed.

In one embodiment, two or more scenes may be coupled to construct one virtual testing scene. Precisely, if at least two of the to-be-tested members are interacted with each other, the scenes of the scene groups corresponding to the at least two of the to-be-tested members are defined as a plurality of coupling scenes, and testing conditions of at least two of the coupling scenes are coupled for generating one of the virtual testing scenes. For example, there are a first to a third to-be-tested members, and each of the to-be-tested members has a first to a tenth scenes. The first to-be-tested member and the second to-be-tested member are interacted with each other, and the first to the tenth scenes of the first to-be-tested member and the first to the tenth scenes of the second to-be-tested member are defined as the coupling scenes, i.e., the first to the twentieth coupling scenes. The scene selecting unit may for example select the testing conditions of the first coupling scene and the second coupling scene, and the simulation testing unit may generate one virtual testing scene including the two testing conditions.

In another embodiment, the testing condition of each of the coupling scenes at least includes a high level condition and a low level condition. In the virtual testing module, the high level condition of a first one of the coupling scenes is used to generate a first one of the virtual testing scenes for testing the to-be-tested system, if the to-be-tested system fails, the low level condition of the first one of the coupling scenes is used to generate a second one of the virtual testing scenes; if the to-be-tested system succeeds, the low level condition of the first one of the coupling scenes is not used to generate the second one of the virtual testing scenes; as the to-be-tested system passes at least one of the first one and the second one of the virtual testing scenes of the first one of the coupling scenes, the to-be-tested system obtains a boundary of the testing condition of the first one of the coupling scenes. If the to-be-tested system succeeds in the first one of the coupling scenes, the first one of the coupling scenes is used to couple to at least another one of the coupling scenes to generate a third one of the virtual testing scenes. As the to-be-tested system does not pass the first one and the second one of the virtual testing scenes of the first one of the coupling scenes, the first one of the coupling scenes does not couple to the at least another one of the coupling scenes to generate the third one of the virtual testing scenes.

For example, the simulation testing unit uses the high level condition, e.g., heavy rain, of the first coupling scene, e.g., raining day, to generate one virtual testing scene. If the to-be-tested system does not fail in the virtual testing scenes, the low level condition, e.g., small rain being smaller than the heavy rain, will not be used to generate another virtual testing scene. On the contrary, if the to-be-tested system fails in the virtual testing scene with heavy rain, the low level condition will be used to generate another virtual testing scene for test. Therefore, the boundary of the raining day of the to-be-tested system may be obtained. A middle level condition between the high level condition and the low level condition may be contained, and the present disclosure is not limited thereto.

In one situation, the to-be-tested system passes the high level condition of the first coupling scene, e.g., raining day, the scene selecting unit may select the high level condition of the first coupling scene and the testing condition of the second coupling scene, and the simulation testing unit uses the high level condition of the first coupling scene and the testing condition of the second coupling scene to generate one virtual testing scene. It is noted that, if the to-be-tested system does not pass both the virtual testing scenes of heavy rain and small rain, the to-be-tested system may not be used in a raining day. Therefore, the testing condition of the raining day will not be coupled with other testing conditions of other coupling scenes owing to a predicted failure. Hence, all the boundaries of the to-be-tested system may be found, and the solving methods may be further analyzed. Moreover, the affecting level or scores of the scenes may be given.

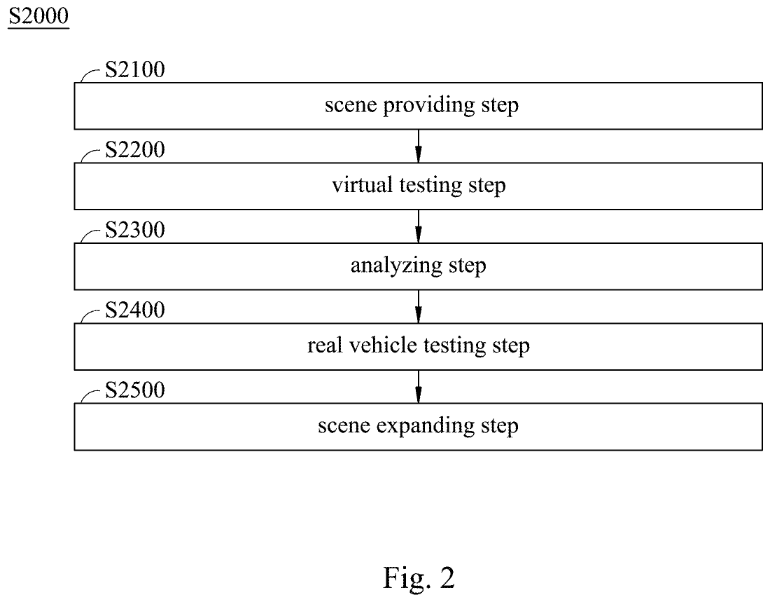

FIG. 2 shows a flow block diagram of a comprehensive SOTIF testing method S2000 according to another embodiment of the present disclosure. The comprehensive SOTIF testing method S2000 includes a scene providing step S2100, a virtual testing step S2200 and an analyzing step S2300.

In the scene providing step S2100, a scene database includes a plurality of scene groups, the scene groups respectively correspond to a plurality of source types, each of the scene groups includes a plurality of scenes, and each of the scenes corresponds to at least one of a plurality of trigger conditions and a plurality of function limitations.

In the virtual testing step S2200, a virtual testing module decides a plurality of to-be-tested members from the source types based on demands of a to-be-tested system, chooses a plurality of chosen members from the scene groups corresponding to the to-be-tested members, generates a plurality of virtual testing scenes based on the scenes of the chosen members, tests the to-be-tested system on the virtual testing scenes, and confirms whether at least one fail member is present in the virtual testing scenes.

In the analyzing step S2300, the analyzing module confirms one of the trigger conditions or one of the function limitations that the at least one fail member in the virtual testing scenes corresponds to so as to provide an improving method.

Therefore, with the scene providing step S2100, the virtual testing step S2200 and the analyzing step S2300, the source types according to the demands may be quickly and comprehensively tested. Contents similar with the comprehensive SOTIF testing system 1000 of FIG. 1 will not be repeated.

The comprehensive SOTIF testing method S2000 may further include a real vehicle testing step S2400. As the to-be-tested system is tested by the virtual testing scenes and the at least one fail member is not present in the virtual testing scenes, the to-be-tested system is installed onto a vehicle, and the vehicle conducts a real test on a real road. After the to-be-test system is tested by the virtual testing scenes and conducts relative improvements, the to-be-test system is safe. Hence, a real test on the real road may be conducted. In the real vehicle testing step S2400, the vehicle keeps testing until a testing terminal condition is satisfied, the testing terminal condition is β=−ln [(1−n)/2α]. α represents a real accident occurring frequency, which is an average occurring quantify of the accident or dangerous issues occurring in per mileage or per period. In other words, in a specific range, different value represents the average occurring quantify of the accident in different situation and capability. B represents a mileage or a period without any accident, and n represents a reliably with failure. As the mileage or the period without any accident achieves B in a specific reliably n, ratio of occurring dangerous issues as the to-be-teste system driving in the same level may achieve the real accident occurring frequency a. The aforementioned real accident occurring frequency, the mileage or the period without any accident, and the reliably with failure may be defined by the manufacturer of the to-be-tested system.

In addition, the comprehensive SOTIF testing method S2000 may further include a scene expanding step S2500. If the to-be-tested system fails in at least one new scene in the real vehicle testing step S2400, the at least one new scene is added into the scene database. Via the real vehicle test, the new scene that is not included in the scene database may be present, and the new scene may be added into the scene database to improve the scene database, and a more comprehensive test may be provided.

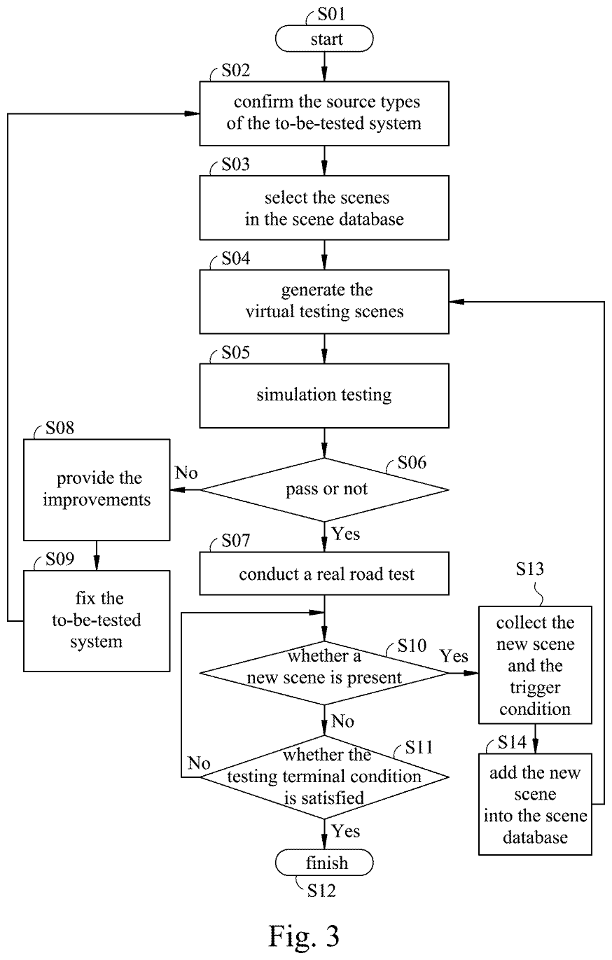

FIG. 3 shows a flow chart of the comprehensive SOTIF testing method S2000 of FIG. 2. In Step S01, the comprehensive SOTIF testing method S2000 starts. In Step S02, the source types of the to-be-tested system, e.g., the camera and the actuator, are confirmed, and the system spec and the operation spec may also be inputted. After which, Step S03 may be executed, and the scene selecting unit selects the corresponding scenes in the scene database. Step S04 may be then executed to generate the virtual testing scenes by the simulation testing unit of the virtual testing module. In Step S05, conduct a simulation testing. It is noted that, in Steps S03 to S05, the virtual testing scenes may be respectively generated by the selected scenes, or the virtual testing scenes may include at least two testing conditions of the coupling scenes selected from the scenes.

Step S06 is executed to confirm whether the to-be-tested system passes the test. If yes, Step S07 may be executed to conduct a real road test. On the contrary, if the to-be-tested system does not pass the test, Step S08 may be executed, and improvements, e.g., modification of algorisms, may be provided. Because each of the scenes corresponds to one trigger condition or one function limitation, the problems needed to be improved correspond to the fail scene may be quickly found. Therefore, Step S09 is executed to fix the to-be-tested system, and then Step S02 is executed again.

In the real road test of Step S07, the vehicle having the to-be-tested system keeps testing. In Step S10, whether a new scene is present is confirmed. If the new scene is present, Step S13 may be executed to collect the new scene and the corresponding trigger condition, and then Step S14 is executed to add the new scene into the scene database. Subsequently, the real road test may be stopped, and Step S04 is executed again. The simulation testing unit of the virtual testing module generates a virtual testing scene corresponding to the new scene, and improvements relative to the new scene may be conducted. The new scene may be used in other tests in the future after being added into the scene database. If the new scene is not present, Step S11 is executed, and whether the testing terminal condition is satisfied is confirmed, that is, confirming whether β=−ln [(1−n)/2α] is satisfied. If not, the vehicle keeps testing; if yes, Step S12 is executed to finish the test.

Based on the aforementioned example, it is known that, in the present disclosure, the unknown risk scenes and the trigger conditions of the to-be-tested system in the designated scenes from the clients or the real scenes may be found via a unified testing method and a specific risk evaluating standard, and the relative improvements may be provided to lower the risk of self-driving vehicles. Additionally, the new scene may found in the real vehicle test may be added, and the scene database is expandable.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A comprehensive SOTIF testing system, comprising:
a scene database comprising a plurality of scene groups, the scene groups respectively correspond to a plurality of source types, wherein each of the scene groups comprises a plurality of scenes, and each of the scenes corresponds to at least one of a plurality of trigger conditions and a plurality of function limitations;
a virtual testing module configured to decide a plurality of to-be-tested members from the source types based on demands of a to-be-tested system, to choose a plurality of chosen members from the scene groups corresponding to the to-be-tested members, to generate a plurality of virtual testing scenes based on the scenes of the chosen members, to test the to-be-tested system on the virtual testing scenes, and to confirm whether at least one fail member is present in the virtual testing scenes; and
an analyzing module configured to confirm one of the trigger conditions or one of the function limitations that the at least one fail member in the virtual testing scenes corresponds to so as to provide an improving method.

2. The comprehensive SOTIF testing system of claim 1, wherein at least two of the to-be-tested members are interacted with each other, the scenes of the scene groups corresponding to the at least two of the to-be-tested members are defined as a plurality of coupling scenes, and testing conditions of at least two of the coupling scenes are coupled for generating one of the virtual testing scenes.

3. The comprehensive SOTIF testing system of claim 2, wherein the testing condition of each of the coupling scenes includes a high level condition and a low level condition, and in the virtual testing module:
the high level condition of a first one of the coupling scenes is used to generate a first one of the virtual testing scenes for testing the to-be-tested system, if the to-be-tested system fails, the low level condition of the first one of the coupling scenes is used to generate a second one of the virtual testing scenes; if the to-be-tested system succeeds, the low level condition of the first one of the coupling scenes is not used to generate the second one of the virtual testing scenes; as the to-be-tested system passes at least one of the first one and the second one of the virtual testing scenes of the first one of the coupling scenes, the to-be-tested system obtains a boundary of the testing condition of the first one of the coupling scenes; and
if the to-be-tested system succeeds in the first one of the coupling scenes, the first one of the coupling scenes is used to couple to at least another one of the coupling scenes to generate a third one of the virtual testing scenes.

4. The comprehensive SOTIF testing system of claim 3, wherein as the to-be-tested system does not pass the first one and the second one of the virtual testing scenes of the first one of the coupling scenes, the first one of the coupling scenes does not couple to the at least another one of the coupling scenes to generate the third one of the virtual testing scenes.

5. The comprehensive SOTIF testing system of claim 1, wherein the source types at least comprises a camera, a radar, an actuator and a human interface.

6. A comprehensive SOTIF testing method, comprising:
a scene providing step, wherein a scene database comprises a plurality of scene groups, the scene groups respectively correspond to a plurality of source types, each of the scene groups comprises a plurality of scenes, and each of the scenes corresponds to at least one of a plurality of trigger conditions and a plurality of function limitations;
a virtual testing step, wherein a virtual testing module decides a plurality of to-be-tested members from the source types based on demands of a to-be-tested system, chooses a plurality of chosen members from the scene groups corresponding to the to-be-tested members, generates a plurality of virtual testing scenes based on the scenes of the chosen members, tests the to-be-tested system on the virtual testing scenes, and confirms whether at least one fail member is present in the virtual testing scenes; and
an analyzing step, wherein an analyzing module confirms one of the trigger conditions or one of the function limitations that the at least one fail member in the virtual testing scenes corresponds to so as to provide an improving method.

7. The comprehensive SOTIF testing method of claim 6, wherein in the virtual testing step, at least two of the to-be-tested members are interacted with each other, the scenes of the scene groups corresponding to the at least two of the to-be-tested members are defined as a plurality of coupling scenes, and testing conditions of at least two of the coupling scenes are coupled for generating one of the virtual testing scenes.

8. The comprehensive SOTIF testing method of claim 7, wherein in the virtual testing step:
a high level condition of a first one of the coupling scenes is used to generate a first one of the virtual testing scenes for testing the to-be-tested system, if the to-be-tested system fails, a low level condition of the first one of the coupling scenes is used to generate a second one of the virtual testing scenes; if the to-be-tested system succeeds, the low level condition of the first one of the coupling scenes is not used to generate the second one of the virtual testing scenes; as the to-be-tested system passes at least one of the first one and the second one of the virtual testing scenes of the first one of the coupling scenes, the to-be-tested system obtains a boundary of the testing condition of the first one of the coupling scenes; and
if the to-be-tested system succeeds in the first one of the coupling scenes, the first one of the coupling scenes is used to couple to at least another one of the coupling scenes to generate a third one of the virtual testing scenes.

9. The comprehensive SOTIF testing method of claim 8, wherein in the virtual testing step, as the to-be-tested system does not pass the first one and the second one of the virtual testing scenes of the first one of the coupling scenes, the first one of the coupling scenes does not couple to the at least another one of the coupling scenes to generate the third one of the virtual testing scenes.

10. The comprehensive SOTIF testing method of claim 9, further comprising a real vehicle testing step, wherein as the to-be-tested system is tested by the virtual testing scenes and the at least one fail member is not present in the virtual testing scenes, the to-be-tested system is installed onto a vehicle, and the vehicle conducts a real test on a real road.

11. The comprehensive SOTIF testing method of claim 10, wherein in the real vehicle testing step, the vehicle keeps testing until a testing terminal condition is satisfied, the testing terminal condition is β=−ln [(1−n)/2α], α represents a real accident occurring frequency, β represents a mileage or a period without any accident, and η represents a reliably with failure.

12. The comprehensive SOTIF testing method of claim 10, further comprising a scene expanding step, wherein if the to-be-tested system fails in at least one new scene in the real vehicle testing step, the at least one new scene is added into the scene database.
